(19) United States
(12) Patent Application Publication
(10) Pub. No.: US 2025/0393481 A1
(43) Pub. Date: Dec. 25, 2025

(54) HORSESHOE-TYPE JOSEPHSON JUNCTION DEVICE AND METHOD OF MANUFACTURING THE DEVICE

(71) Applicants: PETRÓLEO BRASILEIRO S.A. - PETROBRAS, Rio de Janeiro (BR); CENTRO BRASILEIRO DE PESQUISAS FISICAS - CBFP, Rio de Janeiro (BR)

(72) Inventors: Eldues Oliveira Martins, Rio de Janeiro (BR); Ivan Dos Santos Oliveira Junior, Rio de Janeiro (BR); Joäo Paulo Sinnecker, Rio de Janeiro (BR); Arthur Chianelli Monteiro Rebello, Rio de Janeiro (BR)

(21) Appl. No.: 19/237,964

(22) Filed: Jun. 13, 2025

(30) Foreign Application Priority Data
Jun. 21, 2024 (BR) BR1020240127714

(51) Int. Cl. H10N 60/01; C23C 14/02; C23C 14/20; C23C 14/30; C23C 14/58; H10N 60/12

(52) U.S. Cl. CPC H10N 60/0912; C23C 14/022; C23C 14/024; C23C 14/20; C23C 14/30; C23C 14/5853; H10N 60/12

(57) ABSTRACT

The present invention relates to a horseshoe-type Josephson junction device and a method of manufacturing the device. The method of manufacturing is an improved method of manufacturing Josephson junctions by using 30 kV electron beam lithography in conjunction with the Dolan technique. While the 30 kV electron beam process is well documented in terms of steps and process, the geometry and contribution of backscattered electrons have not been correlated. The present invention addresses the challenge of reproducibility by improving the accuracy and consistency of the method of manufacturing. It is demonstrated that choosing appropriate geometries significantly increases the chances of success, as some designs are more robust to small variations in process parameters than others, a critical step toward reliable and scalable superconducting quantum circuits for the 30 kV electron beam process.

### FIELD OF THE INVENTION

The present invention falls within the technical field of oil and gas, specifically related to supply and biofuels, energy and renewable resources, and relates to a horseshoe-type Josephson junction device and the method of manufacturing said Josephson junction device.

### BACKGROUND OF THE INVENTION

Josephson junctions are one of the main components that make up superconducting quantum processing units and are equivalent to non-linear inductors that are operable only in the quantum regime. These devices allow the creation of harmonic oscillators, which from a physical point of view work in a similar way to the energy levels of an electron around an atomic nucleus.

A Josephson junction, by definition, is composed of two superconducting materials that are close enough for the superconducting particles to tunnel from one material to the other. Tunneling is a quantum phenomenon that cannot be observed in conventional materials, obviously.

Furthermore, given a certain state of this system, this tunneling is periodic, and its energy levels are non-linear, enabling the creation of artificial atoms in these devices.

Thus, with Josephson junctions it is possible to create systems that behave like artificial atoms, objects that are equivalent to transistors in classical computing. These devices can be manipulated with microwave waves, thus allowing quantum algorithms to be processed in these devices.

The geometries commonly used in nanolithography to create Josephson junctions are Manhattan and Dolan, in the case of the present invention it would be a new type of junction within those classified as Dolan. These junctions are made from a bridge that is lithographed in resist (polymer) of two layers.

A first sensitive layer with a thickness of 500 to 1000 nm and a second hard layer that forms the bridge of 100 to 300 nm. This bridge serves to create a shadow during the deposition of metal films, thus allowing the creation of the junctions.

Since these are manometric scales, even the largest companies and the most sophisticated nanofabrication centers have difficulty in reproducibility. Therefore, the technical problem is related to the difficulty in achieving reproducibility in Josephson junctions, and the limitations of existing technologies.

In view of the above, in order to solve the limitations and technical problems described above, the present invention describes a device for a horseshoe-type Josephson junction and an improved method of manufacturing Josephson junctions using 30 kV electron beam lithography in conjunction with the Dolan technique. Although the 30 kV electron beam process is well documented in terms of steps and process, the geometry and contribution of backscattered electrons have not been correlated.

The present invention addresses the challenge of reproducibility by improving the accuracy and consistency of the manufacturing process. It is demonstrated that choosing appropriate geometries significantly increases the chances of success, as some designs are more robust to small variations in process parameters than others, a critical step towards reliable and scalable superconducting quantum circuits for the 30 kV electron beam process.

### STATE OF THE ART

The Osman document is part of the general state of the art and describes the reliability and reproducibility of the manufacturing process of Al/AlOₓ/Al Josephson junctions with varying sizes using the cross-type lithography technique. In addition, two steps to optimize the manufacturing process s are investigated (Osman, A. Reliability and reproducibility of Josephson junction fabrication-Steps towards an optimized process. Master's thesis. Chalmers University of Technology, Sweden. Gothenburg, 2019. Page 74).

It should be noted that the entire process described in the aforementioned document is performed at 100 Kv, i.e., the method differs from that of the present invention in this first aspect. The 20/30 kV equipment came first, modifying scanning microscopes for lithography, as this was a diversion from the purpose, there were problems, and to solve the related problems and increase the resolution, the 100 kV equipment came.

In its turn, the document EP 4009387 B1 describes a method of manufacturing Josephson junctions such as may be suitable for use in qubits. It is described that the first and second electrode layers are made of aluminum and the dielectric layer is an aluminum oxide, and that the aluminum oxide of the dielectric layer has a monocrystalline structure.

It should be noted that the manufacturing methods are different when we compare the method of the previous document with that of the present invention. And they are limited by the techniques applied. For example, for squids, which are interferometers composed of two Josephson junctions, the area formed by the junctions is a fundamental characteristic of the device.

Ideally, the device should be very small, especially when the purpose is quantum computing. In the present invention, it was possible to make areas of 10 by 10 microns. However, the means used to perform the technique of this document EP 4009387 B1, photolithography and multiphoton lithography (laser lithography with 3D application), have much greater resolution limitations than electron beam lithography techniques, which allow junctions of 100 nm×100 nm, as used in the present invention.

The Freitas document describes the construction of bridge-type Josephson junctions, manually constructed in a BSCCO film. To obtain the Josephson junctions, a good quality powder with nominal composition Bi_{1.8}Pb_{0.4}Sr₂CaCu₂O₈ was deposited on a crystalline substrate of lanthanum aluminate (LaAlO₃), then heat-treated using a conventional microwave oven (2.45 GHz, 800 W), to cause coalescence of the powder on the substrates (De Freitas, G. G. Construction of a Josephson junction in superconducting thin films of the Bi_{1.8}Pb_{0.4}Sr₂CaCu₂O₈ system heat-treated in a domestic microwave oven. Master's Thesis. UNESP, São Paulo, Brazil, 2012. Page 81).

Finally, the document U.S. Pat. No. 11,349,059 B2, which is also part of the general state of the art, describes a Josephson junction device and a method of manufacturing the same. The Josephson junction device includes a planar arrangement including a first layer of two-dimensional (2D) material, a graphene layer and a second layer of 2D material arranged planarly on a device substrate.

Thus, in view of these documents, it is important to emphasize that these nanometric processes are extremely delicate, and each technique will achieve different results. Whether in terms of resolution, dimension or crystallographic properties of the material, which may or may not be advantageous when used in such a way that it is allowed using a certain technique and not another.

Thus, considering the above, it is possible to perceive relevant differences between the solutions from the state of the art in relation to the present invention and it is also possible to verify the presence of a differential technical effect in the present invention, considering the intrinsic advantages of the “horseshoe” type Josephson junction device and its manufacturing method.

### BRIEF DESCRIPTION OF THE INVENTION

The present invention relates to a horseshoe-type Josephson junction device and the method of manufacturing the Josephson junction. The method of manufacturing is an improved method of manufacturing Josephson junctions by using 30 kV electron beam lithography in conjunction with the Dolan technique. Although the 30 kV electron beam process is well documented in terms of steps and process, the geometry and contribution of backscattered electrons have not been correlated. The present invention addresses the challenge of reproducibility by improving the accuracy and consistency of the fabrication process. It is demonstrated that choosing appropriate geometries significantly increases the chances of success, as some designs are more robust to small variations in process parameters than others, a critical step towards reliable and scalable superconducting quantum circuits for the 30 kV electron beam process.

### BRIEF DESCRIPTION OF THE FIGURES

In order to obtain a complete and total view of the object of this invention, the figures to which references are made below are presented.

FIG. 1 shows a diagram of the exposed pattern on a double resist (polymer) layer after development, in which a) Dolan Josephson Junction design illustrating the exposed region (in dark blue) and the bridge region in the center (in gray), b) Aerial view of the expected Josephson Junction bridge structure, c) First 30° angle deposition, d) oxidation, e) Second −30° deposition, f) Josephson Junction diagram after removal, wherein the green coating indicates the AlOₓ layer, g) Spot scattering trajectories for electron paths in 230 nm PMMA (polymethyl methacrylate) (top) and 500 nm MMA (methyl methacrylate-methacrylic acid copolymer) copolymer (bottom), placed on a silicon substrate for a 30 kV electron beam, wherein the primary electrons of the incident beam are represented by blue lines, while the backscattered ones are red, and h) Diagram describing the circuit configuration used to measure Josephson junctions at room temperature.

FIG. 2 schematically represents an image of the SEM (Scanning Electron Microscope) of the “horseshoe” Josephson junction, developed in the present invention.

FIG. 3 schematically represents an image of the SEM (Scanning Electron Microscope) of the “horseshoe” Josephson junction: on the left side, seen at an angle, on the right side, seen from above.

FIG. 4 schematically shows a graph demonstrating the dose variation supported by each geometry.

FIG. 5 represents: a) Simulation of backscattered angle versus energy, wherein the green dashed line represents the 20 region, b) Diagram of the electron beam during exposure, at the substrate interface, the most likely scattering direction is shown, c) Radius of the simulated energy surface of backscattered electrons.

FIG. 6 shows: a) From left to right, thin, middle, wide, L and horseshoe-shaped junctions and b) The resulting dose maps of both the incident beam and the backscattered electrons, which are calculated by integrating over the point scattering function of the beam within the geometry. On the left, thin Dolan junction, in the middle, L, on the right, horseshoe-shaped junction.

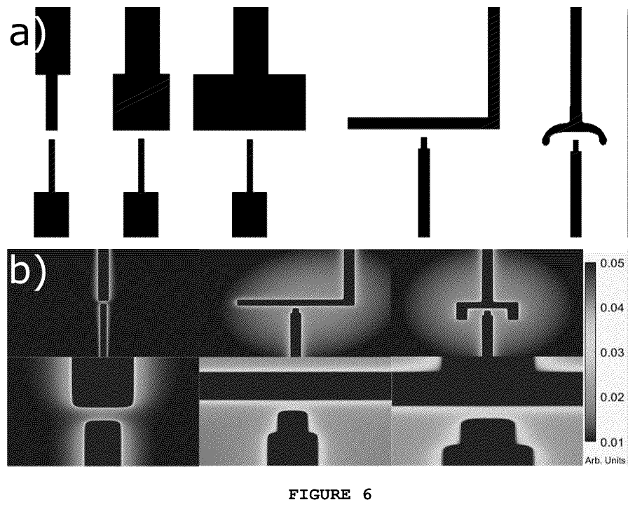

FIG. 7 schematically represents a graph that relates the resistance measurement of a junction with the dose applied in the electron beam nanolithography step.

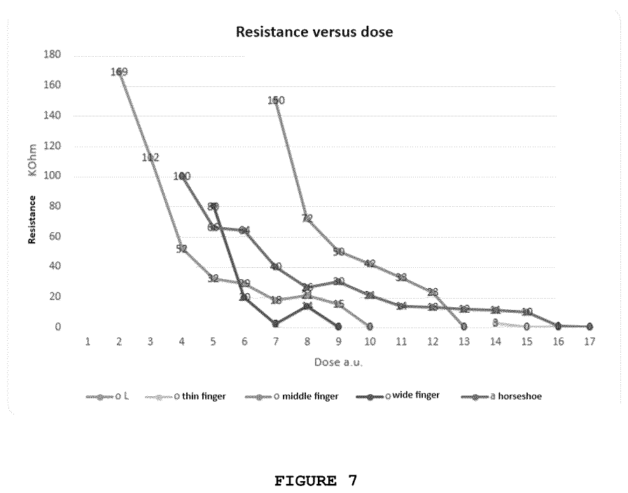

FIG. 8 represents a preferred configuration of the Josephson junction of the present invention, highlighting the layers of materials and the components used.

FIG. 9 schematically represents some examples of junctions, wherein from left to right, thin, middle, wide, L and horseshoe-shaped junctions (proposed in the present invention).

### DETAILED DESCRIPTION OF THE INVENTION

The present invention relates to a horseshoe-type Josephson junction device (superconducting devices) and an improved method of manufacturing Josephson junctions by using 30 kV electron beam lithography in conjunction with the Dolan technique. Although the 30 kV electron beam process is well documented in terms of steps and process, the geometry and contribution of backscattered electrons have not been correlated. The present invention addresses the challenge of reproducibility by improving the accuracy and consistency of the fabrication process.

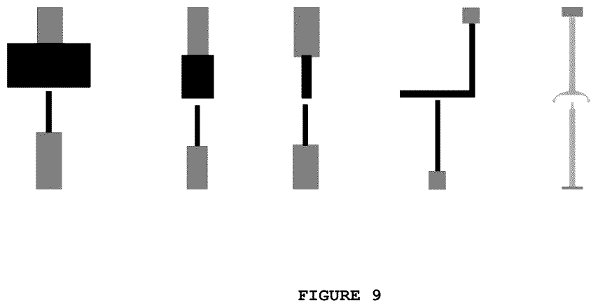

As shown in FIG. 9, the “horseshoe” geometry is on the right (in green). This pattern will be lithographed onto the polymer to be sensitized. It is shown that choosing appropriate geometries significantly increases the chances of success, as some designs are more robust to small variations in process parameters than others, a critical step towards reliable and scalable superconducting quantum circuits for the 30 kV electron beam process.

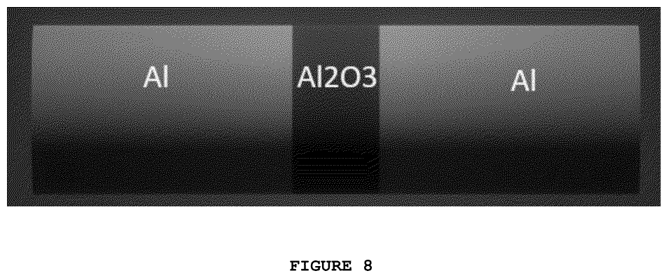

A preferred configuration and preferred components for the developed Josephson junction are shown in FIG. 8. That is, two outer Aluminum (Al) layers surrounding a central Aluminum Oxide (Al₂O₃) layer.

The method of manufacturing the Josephson junction is described below, beginning with a discussion of Electron Beam Lithography, followed by detailing the sample preparation methods. The method of manufacturing the Josephson junction is explained, including the deposition of ultrapure Aluminum and the controlled formation of the oxide barrier. It concludes with a description of room temperature measurements.

Circuits were developed that enabled probe testing of hundreds of Josephson junctions manufactured on the same sample to minimize variations. These circuits were created using optical lithography on a laser lithography tool or a high-resolution direct-write pattern generator.

In general, the manufacturing process of the present invention involves depositing thin films, selectively etch materials using wet etching for Aluminum (Al) or SF6 RIE plasma etching for Niobium (Nb).

Subsequently, using a 30 kV EBL Dolan technique process in a multifunctional electron beam lithography (EBL) system, the Josephson junctions were precisely created. For room temperature measurements, a Lock-In (technique used and device name) with a contact needle probe was used, while measurements in the mK range were performed in a Dilution Refrigerator.

To understand how the electron beam interacts with the sample, the Casino software was used to simulate the trajectories of the electrons interacting with the sample. The electron trajectories are simulated using the Monte Carlo Method. The aim is to explore how the process that results in the characteristic bridge pattern formed to produce Josephson junctions can be optimized.

Electron beam lithography stands out as a precise and versatile nanofabrication technique that employs a focused electron beam to outline nanoscale structures on a substrate. These systems easily achieve a spot size resolution of 20 nm, however, the recesses required for the manufacture of Josephson junctions are created from backscattered electrons, and their distribution must be considered when defining patterns for these applications.

The selection of lithography parameters and geometric features is of fundamental importance in defining the properties of Josephson junctions. Electrons, with their complex behavior and interactions dictated by the intrinsic properties of the sample setup, are central to this process.

To obtain reproducible results, the manufacturing process must show resistance to minor process variations. Here it is meticulously demonstrated how geometric considerations can significantly increase the reproducibility of bridge formation during electron beam exposure.

The first step or step (a) consists of the “Deposition of resist” (acrylic, but in its liquid form) to form the lower layer, and to perform this deposition, an ultra-flat Si sample, without dopant, with high resistivity of 20 kOhm/cm² is used.

PMMA resists are composed of polymethacrylates with different molecular weights (50K, 200K, 600K and 950K) dissolved in chlorobenzene (AR-P 631 . . . 671) or in solvents such as anisole (AR-P 632 . . . 672), ethyl lactate (AR-P 639 . . . 679) or 1-methoxy-2-propyl acetate (AR-P 6510). These products can be obtained from the company ALLRESIST, for example. All resists work positively. The 50K polymer is characterized by a 20% higher sensitivity compared to the 950K polymer. The glass transition temperature of PMMA films is about 105° C., and the polymers are temperature stable up to 230° C. PMMAs are characterized by excellent resolution. For example, 6 nm lines with an aspect ratio of 10 can be obtained for AR-P 679.02. Special resists are the AR-P 6510 PMMA series resists that allow the generation of very thick films (62 to 250 μm) for LIGA technologies.

Copolymer resists such AR-P 617 are composed of copolymers based on methyl methacrylate and methacrylic acid (PMMA/MA 33%), dissolved in the safer solvent 1-methoxy-2-propanol. CSAR 62 (AR-P 6200) is based on styrene acrylates dissolved in the safer solvent anisole. The copolymer resists perform positively and exhibit a 3 to 4 times higher sensitivity compared to PMMA resists. Furthermore, the copolymer layers are temperature stable up to 240° C.; the glass transition temperature for AR-P 617 is about 150° C. and approximately 148° C. for CSAR 62. Above a wavelength of 260 nm, the PMMA and copolymer layers are optically transparent. Since these resists also absorb at 248 nm, deep UV irradiation and structuring are possible, albeit with lower sensitivity.

For the bottom resist layer, a copolymer composite was chosen that has a 3 to 4 times higher sensitivity than commercially available PMMA resists. For example, from the company ALLRESIST (www.allresist.com), but not limited to this, and can be obtained via synthesis or from other suppliers. More specifically, MMA AR-P 617.08 (copolymer based on methyl methacrylate and methacrylic acid) which results in 500 nm when applied at 4000 rpm for approximately 60 seconds.

Then, in step (b), the “Heating of sample” occurs at approximately 200° C. for approximately 10 minutes. Then, in step (c), a new “Deposition of resist” occurs to form the top resist layer, with subsequent “Heating of sample” at 200° C. for 10 minutes in step (d).

For the top resist layer, PMMA 950k was chosen to achieve an optimal thickness of AR 672.045, which results in 230 nm when applied at 4000 rpm. The first layer is heated to 200° C. and the second to 180° C. for 10 minutes each.

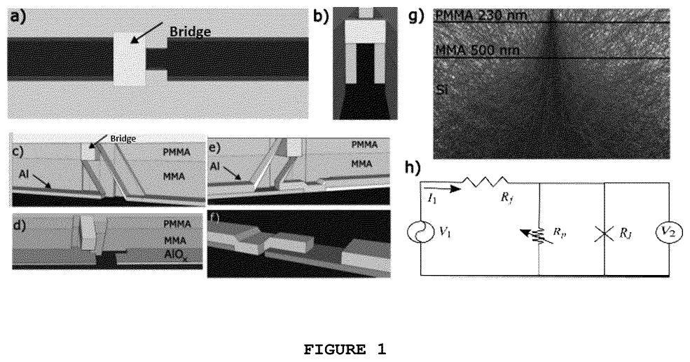

Essentially, the goal is to form a bridge, as shown in FIG. 1a to d. As can be seen from the aforementioned figure, the difficulty lies in using a straight beam to carve laterally under the top polymer layer. This is achieved primarily through interaction with backscattered electrons, taking advantage of the discrepancy in material sensitivity.

Backscattered electrons are illustrated in FIG. 1g with red trajectories. It is explored how these electrons behave and how this influences the double resist bridge for the fabrication of Josephson junctions.

Josephson junctions need to be fabricated in a single process to avoid contamination. Exposing the junction to the atmosphere would cause its complete oxidation with contaminants.

Following step (d), described above, step (e) is performed wherein the “Samples are exposed to the 30 kV backscattered electron beam, followed by step (f) wherein the “Samples are developed” in MIBK (methyl isobutyl ketone) 3:1 isopropanol (IPA) for 60 seconds and rinsed in isopropanol (IPA) to stop the process for 30 seconds.

In step (g), the “Transfer of sample” takes place to the deposition chamber for deposition of thin aluminum films and oxidation. The process begins by depositing ultra-pure aluminum (Al) (99.999%) at an angle of 30°, as shown in FIG. 1c.

Electron beam vapor deposition is chosen because it is performed in ultra-fast high vacuum (UHV-10⁻⁹ torr), a crucial factor in reducing impurities. In addition, this allows a large mean free path in the chamber.

With this, the sample is placed approximately one meter from the crucible, and thus it is possible to perform an anisotropic deposition. After the deposition of the first layer, the sample is moved to a separate chamber, where step (h) takes place with the “Controlled exposure of the samples to O₂ at 5.7 Torr to form the oxide barrier”, as shown in FIG. 1d. This time may vary depending on the expected results.

At the pressure mentioned above, it takes about a minute to form an atomic layer, and after about 15 minutes, the oxide has grown to its maximum. When the entire Al surface reacts, the process stops, as the oxide prevents the reaction from continuing. This is why aluminum is so resistant to weather and sea spray.

Next, the penultimate step (i) occurs, wherein the “Samples are returned to the deposition chamber” where a second Al layer is deposited at an angle of 30°, as shown in FIG. 1e. After the deposition process, the sample undergoes the final lift-off procedure (step j), revealing the structures shown in FIG. 1f.

At room temperature (about 25° C.), the resulting thin oxide barrier has a characteristic resistance that varies significantly from a few Ohms, depending on the area and size of the junction, to tens of kOhms.

This resistance at room temperature is proportional to the barrier potential experienced by the superconducting particles. Optimizing this resistance provides a means of efficiently tuning the performance of these devices.

The Josephson junctions were measured using a contact probe station. The circuit can be seen in FIG. 1h. Essentially, the current I1 is limited by a resistor Rf and the internal potentiometer resistor Rp. It is known what the applied voltage V₁ is, by measuring the voltage V₂ across the junction, the junction resistance is given by:

$${R}_{J} = \frac{{V}_{2} {R}_{p} {R}_{f}^{2}}{{V}_{1} {R}_{p} {R}_{f} - {V}_{2} {R}_{f} ( {R}_{p} + {R}_{f} )}$$

Obtaining constant resistance measurements for multiple junctions at room temperature requires following a well-optimized recipe. Despite meticulous optimization, the inherent sensitivity of the manufacturing process will still result in oscillations. This highlights the delicate nature of this process and the need for means to improve reproducibility.

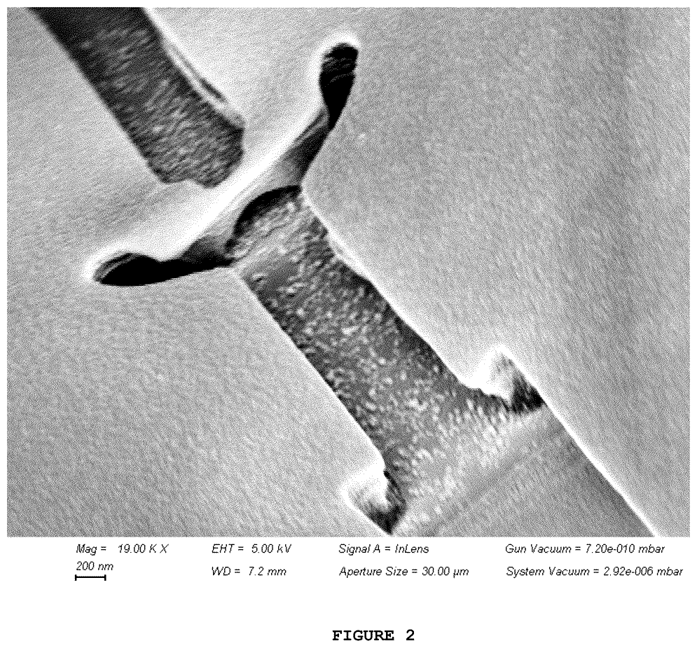

FIG. 2 shows a scanning microscope image of the lithographed pattern that results in the horseshoe junction. It is worth noting that the electron beam that sensitizes the resist (polymer) is the same one used to make the image, which means that when making the image the quality of the structure is damaged, the equipment used does not have dynamic focus, and since the sample is at an angle greater than 70°, it is only possible for a band of the image to be in focus.

A layer of approximately 40 nm of gold was deposited on top of the resist (acrylic, but in its liquid form) by benchtop magnetron sputtering. This procedure is standard for viewing lithographed patterns, so that the effect of deterioration is mitigated during imaging.

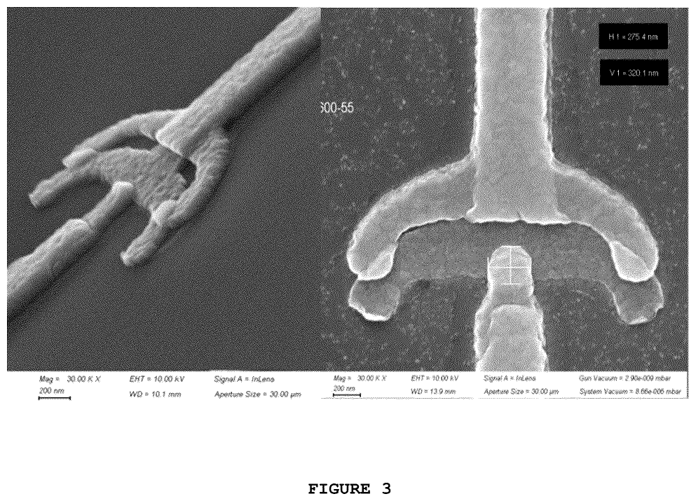

In FIG. 3, it is possible to see the bridge in more detail, as well as the lateral indentations, which results in more stable bridges and a process with a higher success rate. Since local oscillations of parameters mean that defects always exist.

Thus, it is clear that the delicacy of this process comes from the high standard of accuracy required to manufacture these devices. The problem of reproducibility comes from the need to maintain parameters such as the temperature of the reagents and the temperature and humidity to which the samples are exposed unchanged.

Ideally, the variation of these parameters must be minimal for the process to be reproducible. And yet there are other parameters that can vary, such as processing time and, also, lithography limits.

### EXAMPLE OF IMPLEMENTATION

Five (5) geometries were chosen for testing, measuring the dose-dependent room temperature resistance. The geometries tested are shown in FIG. 9.

They were tested at progressive doses, from subdoses to overdoses, with proximity correction. Specifically, it was from 350 to 870 (micro coulombs/cm squared), with intervals of 20 (micro coulombs/cm squared). The goal was to isolate the impact of geometric factors on the resilience to dose variation.

Test pads were created for hundreds of junctions in order to minimize the variation of all other process parameters and to produce all junctions within the same chip. Essentially, at sufficiently low doses, only the illustrated pattern is revealed, but without the formation of a bridge, which makes the measured resistance equivalent to an open circuit.

The reason is that low doses generally do not produce enough backscattered electrons to create large indentations. Therefore, only the pattern is revealed, but the bridge region with MMA (methyl methacrylate and methacrylic acid copolymer) remains.

As one progresses to measuring junctions exposed to higher doses, the bridge structure begins to be formed and a resistance is measured. As the dose increases, the bridge space widens, meaning that the first junction has the highest possible resistance and the smallest junction area.

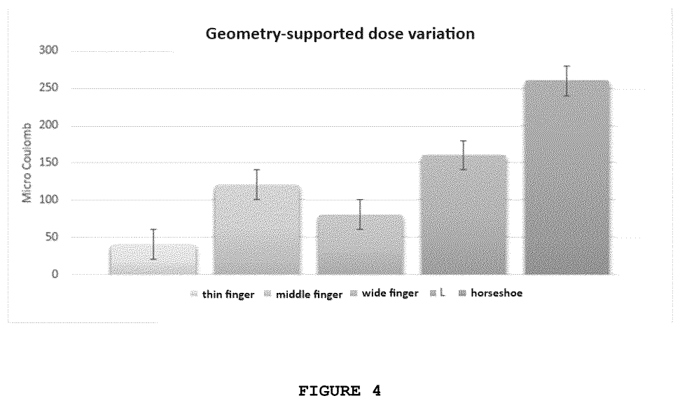

The junction area increases as the dose increases and consequently the measured resistance decreases until the dose deposited in the bridge region is so high that the PMMA is destroyed, the circuit closes, and a short circuit is measured. The results of the dose variation are shown in the graph in FIG. 4.

To explain this, simulations of the electron beam trajectories interacting with the sample were used. To simulate the electron trajectory, the sample was configured using two resist layers and another being the substrate (as seen in FIG. 1g).

The first layer had a PMMA density of 1.14 g/cm³ and the second of a copolymer based on methyl methacrylate and methacrylic acid, solvent 1-methoxy-2-propanol 0.80 g/cm³ of the copolymer. The substrate used was silicon with a density of 2.33 g/cm³.

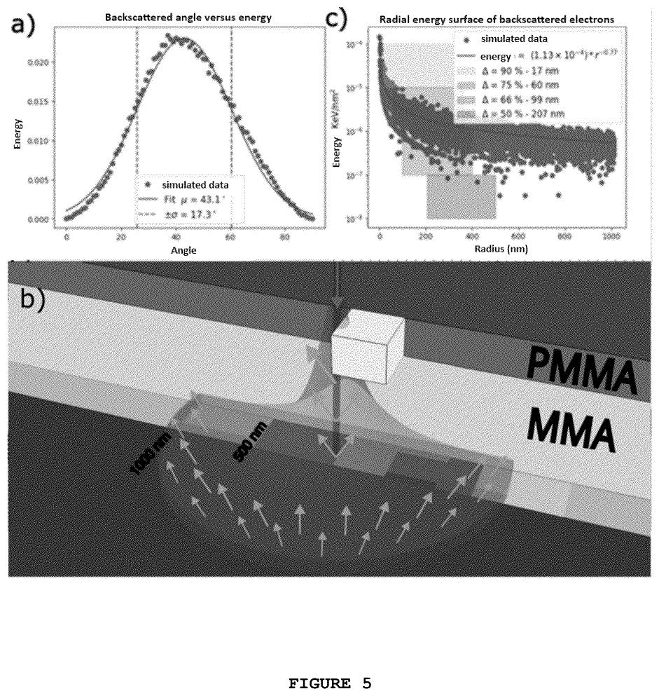

As shown in FIG. 5, the data were collected by simulating 2 million electron trajectories with a beam radius of 10 nm and beam energy of 30 kV. From this, information about the backscattered electrons was obtained.

In FIG. 5b, it is important to note that this is an illustration, and the beam does not reflect all at once when it hits the substrate. However, the diagram correctly illustrates the angle at which most of the most energetic particles are scattered for a given point on the Z axis.

The simulation provides a distribution that correlates the backscattering angle with the deposited energy; this graph can be seen in FIG. 5a. By fitting the data to a normal distribution, it can be shown that the highest energy electrons are being deflected at μ=43.1° and σ=17.3°.

To visualize this process, one can refer to FIG. 5c. This diagram represents a scattering event occurring on the substrate, with the most likely and energetic event being represented in the diagram. It can be seen that exposed regions close to the junction can project backscattered electrons directly into the PMMA layer, causing unwanted damage.

The 30 kV electron beam penetrates the substrate up to 12 μm, according to the simulation. Therefore, the diagram represented in FIG. 5b is not sufficient to fully understand the process of interaction of the sample with the electron beam.

Regarding FIG. 5c, when fitting the data, stability sections are defined in the 300 nm energy distribution. Closer to the beam, in highly unstable regions, at a distance of 17 nm from the beam, the energy distribution will decay by 90% over 300 nm.

To gain a deeper understanding in a more deterministic manner through the cumulative energy distribution, one turns to the surface radius of backscattered electrons; by fitting this distribution, one can see that the energy distribution decreases radially from the incident beam point, according to the power law, depicted in FIG. 5c.

In the context of the data set, the power law decay is represented by the equation P(x)∝x−α, where P(x) is the probability density function, x is the variable, and α is the power law exponent. In analysis, the pattern is described by the equation Energy=a·Radius−b. The parameters a and b are obtained by curve fitting.

The equation (1.13×10\hat{ }−4)*r\hat{ }−0.77 represents the decay of the energy distribution. In order to expose subcut features of a few hundred nanometers, there is necessarily a stability threshold that must be met in order to selectively expose the resist and produce bridge-like structures.

Therefore, section lengths were defined where a desired stability threshold is maintained, a threshold range of 50% to 90% was chosen. 75% being the theoretical upper limit for successful undercut fabrication. In order the deposited energy to decay by only 50% over a 400 nm section, this section must start 276 nm from the incident beam spot.

In the simulations, some conclusions can be drawn about how geometries affect the overall reproducibility. It is argued that high doses close to the junction area cause it to be hit by surface backscattered electrons, which may have spent little or no time in the copolymer region before reaching the PMMA.

For completeness, it can also be stated that backscattered electrons from a more distant incidence point would come from deeper in the Si substrate, necessarily reaching the copolymer layer first. To mitigate large doses close to the junction area, geometries that have doses from more distant incidences can be used, providing the junction area with smaller but more homogeneous doses from distributed regions, as occurs with the L-shaped junction.

To demonstrate this, the Point Scattering Function, calculated from Monte Carlo simulations using Casino software Urpec (MATLAB Opensource Package), was integrated over different geometries, showing how the geometry affects the total dose deposited over the junction. This can be seen in FIG. 5b. Starting from the same dose applied per incidence position, it can be seen that the horseshoe-shaped junction has twice the amount of dose deposited than the thin Dolan junction over the bridge area.

This shows that a lower dose is required near the junction area to form the bridge structure, while preserving the PMMA structure for the reasons mentioned above. This results in a bridge structure that remains stable over a dose range of 260 μC/cm², whereas the Dolan fine structure is only stable over a range of 40 μC/cm².

Having such a short window for process success can drastically decrease the chances of success. A small change in temperature or development time can render samples unusable.

The results show that the horseshoe junction is more robust against process variations, and the simulations demonstrate how the dose is better distributed in the bridge area, thus resulting in more reproducible junctions.

According to this model, most of the dose applied at a given position within the geometry is absorbed by the resist or substrate directly below it, within the provided electron beam resolution. In the process of interaction with the sample, only 13.2% (according to simulated results) of the incident electrons are backscattered for the resist and substrate configuration described above.

Furthermore, they are scattered in all directions, and the backscattered electrons can be detected up to 4 μm from the incident beam. This implies both that the incident beam region is completely exposed before the surrounding resist presents a significant undercut, and that all exposed structures within a 4 μm radius contribute to the total dose deposited on the PMMA bridge structure.

Taking both of these concepts into account, the optimized geometry would have a sufficient exposed area within a 4 μm radius of the junction area to eliminate the need for extreme overdosing, which causes deterioration of the PMMA bridge structure.

### Applicability

The junctions developed herein can be applied in quantum computing, which is an embryonic technology, and the more efficient method for producing Josephson junctions, addressed in the present invention, would improve the amount of good junctions produced on a given chip, achieving a reproducibility of 96% (26/27) good junctions. The best performance that existed in the state of the art for n>10 joints was 50 to 70%.

Those skilled in the art will value the knowledge shown herein and will be able to reproduce the invention in the modalities discloses and in other variants, covered by the scope of the attached claims.

1. A Josephson Junction Device, comprising:
a horseshoe shape; and
two external aluminum layers surrounding a central aluminum oxide layer,
wherein the aluminum layers are formed from a bridge formed by means of two lower and upper polymer layers.

2. The device, according to claim 1, wherein the polymer of the lower layer is a copolymer based on methyl methacrylate and methacrylic acid, solvent 1-methoxy-2-propanol.

3. The device, according to claim 1, wherein the polymer of the upper layer is polymethyl methacrylate.

4. The device, according to claim 1, wherein a thickness of the upper layer is preferably 150 nm to 230 nm and a thickness of the lower layer is preferably 500 nm to 600 nm.

5. A device, according to claim 1, wherein:
the lower layer is a copolymer based on methyl methacrylate and methacrylic acid with a density of 0.80 g/cm³; and
the upper layer is polymethyl methacrylate with a density of 1.14 g/cm³.

6. A method of manufacturing a Josephson Junction Device, comprising the steps of:
a) deposition of a lower layer of resist copolymer based on methyl methacrylate and methacrylic acid;
b) heating the lower layer to 200° C. for 10 minutes;
c) deposition of an upper layer of resist made of polymethyl methacrylate 950k;
d) heating the upper layer to 180° C. for 10 minutes;
e) exposure of samples using a 30 kV backscattered electron beam;
f) development of the samples in methyl isobutyl ketone and isopropanol, ratio 3:1, respectively, and rinsing of the samples in isopropanol;
g) transfer and insertion of the samples into a deposition chamber for oxidation and deposition of thin aluminum films at an angle of 30° to normal;
h) exposure of the samples to O₂ at 5.7 Torr to form an oxide barrier in a separate chamber;
i) return of the samples to the deposition chamber for deposition of a second layer of aluminum at an angle of 30°; and
j) finalization with the samples undergoing a lift-off procedure.

7. A method, according to claim 6, wherein the deposition of step (g) is of ultra-pure aluminum (99.999%) at an angle of 30°.

8. A method, according to claim 6, wherein the deposition of step (g) is of ultra pure aluminum (99.999%) in ultra high vacuum 10⁻⁸ torr.

9. A method, according to claim 6, wherein the deposition of step (g) is anisotropic vapor deposition by electron beam.

10. A method, according to claim 6, the wherein an energy of the electron beam is 30 kV.

11. A method, according to claim 6, wherein the deposition of the lower resist layer of step (a) results in a 500 nm layer when applied at 4000 rpm for 60 seconds.

12. A method, according to claim 6, wherein the deposition of the upper resist layer of step (c) results in a 230 nm layer when applied at 4000 rpm.
